(19) United States
(12) Patent Application Publication
(10) Pub. No.: US 2020/0232118 A1
(43) Pub. Date: Jul. 23, 2020

(54) SUBSTRATE FOR SURFACE ACOUSTIC WAVE ELEMENT AND PRODUCTION PROCESS FOR THE SAME

(71) Applicant: YAMAJU CERAMICS CO., LTD., Owariasahi-shi, AIchi (JP)

(72) Inventors: Ietaka SAHASHI, Owariasahi-shi (JP); Takejji SASAMATA, Owariasahi-shi (JP); Hideki OHASHI, Owariasahi-shi (JP); Masato KURACHI, Owariasahi-shi (JP); Toru YAGI, Owariasahi-shi (JP); Hiroyuki AZUMA, Owariasahi-shi (JP); Naofumi KAJITANI, Owariasahi-shi (JP)

(73) Assignee: YAMAJU CERAMICS CO., LTD., Owariasahi-shi, Aichi (JP)

(21) Appl. No.: 15/755,655

(22) PCT Filed: Jun. 27, 2017
(86) PCT No.: PCT/JP2017/023574

§ 371 Date: Feb. 27, 2018

(30) Foreign Application Priority Data
Jul. 11, 2016 (JP) 2016-136486

(51) Int. Cl. C30B 29/30; C30B 15/00; C30B 33/00; H03H 3/08; H03H 9/02

(52) U.S. Cl. CPC C30B 29/30; C30B 15/00; H03H 9/02559; H03H 3/08; C30B 33/00

(57) ABSTRACT

A substrate for surface acoustic wave element includes: a magnesium/lithium niobate single crystal in which an atomic ratio between Li and Nb satisfies 0.9048≤(Li/Nb)≤0.9685, and whose Mg content proportion is from 1% by mole or more to 9% by mole or less; or a magnesium/lithium tantalate single crystal in which an atomic ratio between Li and Ta satisfies 0.9048≤(Li/Ta)≤0.9685, and whose Mg content proportion is from 1% by mole or more to 9% by mole or less.

### TECHNICAL FIELD

The present invention relates to a substrate for surface acoustic wave element, the substrate used for a surface acoustic wave device, or the like; and to a production process for the same.

### BACKGROUND ART

A lithium tantalate (LiTaO₃) single crystal (abbreviated as “LT single crystal” whenever appropriate), and a lithium niobate (LiNbO₃) single crystal (abbreviated as “LN single crystal” whenever appropriate) have been known as a piezoelectric oxide single crystal, respectively. They have been employed for the piezoelectric substrate of a surface acoustic wave (hereinafter abbreviated as “SAW” whenever appropriate) element, and the like. The SAW element comprises a piezoelectric substrate, and fine comb-shaped electrodes arranged on a surface of the piezoelectric substrate. For example, the SAW element is utilized for SAW filters, SAW duplexers, SAW triplexers, SAW sensors, and so on.

The SAW element is manufactured as follows: an electrode thin film comprising aluminum is formed on the surface of a piezoelectric substrate; and then the electrode thin film is made into an electrode with a predetermined configuration by photolithography. To be concrete, an electrode thin film is first formed on the surface of a piezoelectric substrate by a sputtering method, or the like. Subsequently, an organic resin, namely, a photoresist, is applied onto the electrode thin film, and is then pre-baked under high temperature. Following this, a stepper, or the like, is used to expose the photoresist to light to carry out patterning on the electrode thin film. Then, the electrode thin film is post-baked under high temperature, and is thereafter subjected to developing to dissolve the photoresist. Finally, the electrode thin film is subjected to wet- or dry-etching to form an electrode having a predetermined configuration.

For example, the SAW element has been employed widely as the bandpass filter in a communication instrument, like a cellular phone, and so forth. In recent years, downsizing the filter or height-reducing (or low-profiling) it has been advancing, because the cellular phone is highly functionalized or the number of frequency bands is increased. Moreover, due to the request of upgrading sensors in the detection sensitivity, downsizing the sensors or turning them into a thin plate has been advancing similarly. Being accompanied therewith, it has been requested more strictly to turn a single crystal substrate, which is employed for a piezoelectric substrate in the SAW element, into a thin plate.

However, an LT single crystal substrate or LN single crystal substrate suffers from the poor processibility. That is, cleavage cracks, which are peculiar to single crystals, are likely to occur, so that the single crystal substrates have such a disadvantage as the entire substrate has been cracked by a little bit of impact stress. Moreover, an LT single crystal or LN single crystal has such a characteristic as the thermal expansion coefficient differs remarkably depending on the orientations. Accordingly, when the single crystals are exposed to environments where the temperature changes greatly, stress strains arise in the interior. Consequently, the single crystals may sometimes have cracked instantaneously.

Moreover, devices have been downsized nowadays. In addition, being accompanied by making them highly functional, it has been advanced to laminate a plurality of the SAW elements highly densely. Respective components within the devices might sometimes generate heat when making use of the devices. The SAW elements, which are laminated highly densely within the downsized devices, make heats generated within the devices less likely to dissipate or radiate.

Since it has been further advanced in recent years to laminate the SAW elements highly densely, it is an urgent issue to cope with the heats. It has been an assignment in recent years to solve the issue, namely, to develop a piezoelectric substrate, and the like, which is likely to dissipate or radiate the heats.

### SUMMARY OF THE INVENTION

### Assignment to be Solved by the Invention

The present invention has been done in view of such circumstances, and is aimed at providing a substrate for surface acoustic wave element, substrate which is likely to dissipate or radiate heat, namely, whose thermal conductivity is high.

### Means for Solving the Assignment

Hence, the present inventors studied earnestly or wholeheartedly in order to solve the assignment. As a consequence of their repetitive trials and errors, they discovered that it is possible to fabricate a substrate for surface acoustic wave element, substrate whose thermal conductivity is high, by using a magnesium/lithium niobate single crystal, which contains Mg in a predetermined proportion, or a magnesium/lithium tantalate single crystal, which contains Mg in a predetermined proportion. They thus arrived at completing the present invention.

That is, a substrate for surface acoustic wave element according to the present invention comprises:

a magnesium/lithium niobate single crystal in which an atomic ratio between Li and Nb satisfies 0.9048≤(Li/Nb)≤0.9685, and whose Mg content proportion is from 1% by mole or more to 9% by mole or less; or

a magnesium/lithium tantalate single crystal in which an atomic ratio between Li and Ta satisfies 0.9048≤(Li/Ta)≤0.9685, and whose Mg content proportion is from 1% by mole or more to 9% by mole or less.

Moreover, a production process for a substrate for surface acoustic wave element according to the present invention comprises:

a raw-material mixture preparation step of preparing a raw-material mixture by mixing lithium carbonate (Li₂CO₃) making a lithium source, niobium pentoxide (Nb₂O₅) making a niobium source, and magnesium oxide (MgO) making a magnesium source with each other so as to satisfy following requirements (1) and (2);

(1) an atomic ratio between Li and Nb: 0.9048≤(Li/Nb)≤0.9685; and

(2) an MgO molar ratio with respect to a sum of LiNbO₃ and MgO assuming that LiNbO₃ is generated from Li₂CO₃ and Nb₂O₅: 0.01≤{MgO/(MgO+LiNbO₃)}≤0.09; or another raw-material mixture preparation step of preparing a raw-material mixture by mixing lithium carbonate (Li₂CO₃) making a lithium source, tantalum pentoxide (Ta₂O₅) making a tantalum source, and magnesium oxide (MgO) making a magnesium source with each other so as to satisfy following requirements (3) and (4);

(3) an atomic ratio between Li and Ta: 0.9048≤(Li/Ta)≤0.9685; and

(4) an MgO molar ratio with respect to a sum of LiTaO₃ and MgO assuming that LiTaO₃ is generated from Li₂CO₃ and Ta₂O₅: 0.01≤{MgO/(MgO+LiTaO₃)}≤0.09;

a raw-material mixture melting step of making a raw-material mixture melt by melting the raw-material mixture;

a single-crystal growth step of growing a magnesium/lithium niobate single crystal or magnesium/lithium tantalate single crystal by immersing a seed crystal into the raw-material mixture melt and then pulling it up therefrom; and

a substrate fabrication step of fabricating a substrate from the magnesium/lithium niobate single crystal or magnesium/lithium tantalate single crystal obtained at the single-crystal growth step.

### Advantageous Effects of Invention

The substrate for surface acoustic wave element according to the present invention exhibits a high thermal conductivity. Surface acoustic wave elements whose heat dissipating or radiating property is high are manufactured by using the present substrate.

### BRIEF DESCRIPTION OF THE DRAWINGS

FIG. 1 is a graph for comparing thermal conductivities which a substrate according to Example No. 1 and another substrate according to Comparative Example No. 1 exhibited at various temperatures.

### MODE FOR CARRYING OUT THE INVENTION

### Substrate for Surface Acoustic Wave Element

A substrate for surface acoustic wave element according to the present invention comprises:

a magnesium/lithium niobate single crystal in which an atomic ratio between Li and Nb satisfies 0.9048≤(Li/Nb)≤0.9685, and whose Mg content proportion is from 1% by mole or more to 9% by mole or less; or

a magnesium/lithium tantalate single crystal in which an atomic ratio between Li and Ta satisfies 0.9048≤(Li/Ta)≤0.9685, and whose Mg content proportion is from 1% by mole or more to 9% by mole or less.

Note herein that the “Mg content proportion” means a content proportion of Mg atoms when all atoms constituting the magnesium/lithium niobate single crystal or magnesium/lithium tantalate single crystal is taken as 100% by mole.

The magnesium/lithium niobate single crystal and magnesium/lithium tantalate single crystal are uniform or homogeneous crystals, and exhibit high thermal conductivities.

It is believed at present that an LN single crystal in which an atomic ratio between Li and Nb satisfies 0.9048≤(Li/Nb)≤0.9685, and an LT single crystal in which an atomic ratio between Li and Ta satisfies 0.9048≤(Li/Ta)≤0.968 have a defective structure in which vacancy defects are present at the lithium sites, respectively.

Since heat transmits between crystal lattices while vibrating, a thermal conductivity lowers when the lattices have vacancy defects. When Mg is added to an LN single crystal or LT single crystal, it has been said that the Mg enters a vacancy defect in the lithium site. Thus, it is believed that the thermal conductivity is made higher by making the vacancy defects less in the lattices.

However, when Mg is added excessively or superfluously to an LN single crystal or LT single crystal, the segregation of Mg is likely to arise. Moreover, when excess Mg is arranged at the lithium sites by replacing the lithium atoms, or when excess Mg is arranged at the niobium or tantalum sites, it is presumed that the crystal structure becomes unstable. Moreover, when Mg is segregated to impair the single crystal in the uniformity or homogeneousness, or when excess Mg enters the single crystal to make the crystal structure unstable, it is speculated that the thermal conductivity worsens. Therefore, in order to upgrade the thermal conductivity, the crystal structure is required to be uniform and stable.

In order to make the crystal structure uniform and stable, it is presumed to be important how the content proportion of Mg atoms is related to that of each of the other atoms.

In a magnesium/lithium niobate single crystal used in the present invention, an atomic ratio between the Li and Nb satisfies 0.9048≤(Li/Nb)≤0.9685, and a content proportion of the Mg is from 1% by mole or more to 9% by mole or less. Alternatively, in another magnesium/lithium tantalate single crystal used in the present invention, an atomic ratio between the Li and Ta satisfies 0.9048≤(Li/Ta)≤0.9685, and a content proportion of the Mg is from 1% by mole or more to 9% by mole or less.

When the “Li/Nb” value is 0.9048≤(Li/Nb), alternatively when the “Li/Ta” value is 0.9048≤(Li/Ta), the crystal composition fluctuates less. The less the crystal composition fluctuates, the less the crystal is likely to crack at the time of its preparation. In particular, from the viewpoint of fluctuation in the crystal composition, a suitable “Li/Nb” value or “Li/Ta” value is 0.9421≤(Li/Nb) or 0.9421≤(Li/Ta), more suitably, 0.9425≤(Li/Nb) or 0.9425≤(Li/Ta), much more suitably, 0.9429≤(Li/Nb) or 0.9429≤(Li/Ta).

Moreover, when the “Li/Nb” value is (Li/Nb)≤0.9658, alternatively when the “Li/Ta” value is (Li/Ta)≤0.9658, the crystal composition fluctuates less. The less the crystal composition fluctuates, the less the crystal is likely to crack at the time of its preparation. In particular, from the viewpoint of fluctuation in the crystal composition, a suitable “Li/Nb” value or “Li/Ta” value is (Li/Nb)≤0.9443 or (Li/Ta)≤0.9443, more suitably, (Li/Nb)≤0.9440 or “Li/Tb”≤0.9440, or much more suitably, (Li/Nb)≤0.9436 or (Li/Ta)≤0.9436.

In addition, when the Mg content proportion is 9% by mole or less in the magnesium/lithium niobate single crystal or magnesium/lithium tantalate single crystal, the segregation of Mg is less likely to arise within the single crystal, and the composition is likely to be uniform. The more uniform the crystal composition is, the less cracks are likely to occur at the time of cutting the single crystal to a thin plate. In particular, in the magnesium/lithium niobate single crystal or magnesium/lithium tantalate single crystal, a suitable Mg content proportion is less than 7% by mole, or more suitably, 6% by mole or less.

Moreover, when the Mg content proportion is 1% by mole or more in the magnesium/lithium niobate single crystal or magnesium/lithium tantalate single crystal, the Mg compensates for or fills vacancy defects in the lattices, so that the advantageous effect of raising the thermal conductivity is likely to yield. In the magnesium/lithium niobate single crystal or magnesium/lithium tantalate single crystal, a suitable Mg content proportion is 3% by mole or more, or more suitably, 4% by mole or more.

Since the magnesium/lithium niobate single crystal or magnesium/lithium tantalate contains Mg, it exhibits a Curie temperature risen higher than that of the lithium niobate single crystal or lithium tantalate single crystal. Consequently, it is possible to conveniently judge or determine whether or not Mg is contained in the magnesium/lithium niobate single crystal or magnesium/lithium tantalate single crystal by measuring the Curie temperature of single crystal.

The Curie temperature of a lithium niobate single crystal is at around 1,130° C., whereas the Curie temperature of a lithium tantalate single crystal is at around 603° C. When the Curie temperature of a magnesium/lithium niobate single crystal is from 1,150° C. or more to 1,215° C. or less, it is possible to conveniently judge or determine that it is a magnesium/lithium niobate single crystal whose Mg content proportion is from 1% by mole or more to 9% by mole or less. Alternatively, when the Curie temperature of a magnesium/lithium tantalate single crystal is from 620° C. or more to 720° C. or less, it is possible to conveniently judge or determine that it is a magnesium/lithium tantalate single crystal whose Mg content proportion is from 1% by mole or more to 9% by mole or less.

The substrate for surface acoustic wave element according to the present invention preferably exhibits a volume resistivity of 9.9×10¹² Ω·cm or less, more preferably, 9.9×10¹¹ Ω·cm or less, or much more preferably, 9.9×10¹⁰ Ω·cm or less.

In the manufacturing steps of a surface acoustic wave element, some of the steps, such as the formation of an electrode thin film onto the surface of a substrate and pre-baking or post-baking by photolithography, associate with temperature changes in the substrate. When the volume resistivity of the substrate is too high, the temperature changes may result in generating electric charges on the surface of the substrate. The electric charges, which have occurred once, accumulate on the substrate to keep the substrate being charged, unless the substrate undergoes to a charge removal or neutralization treatment from the outside. When the substrate is charged, electrostatic discharges arise within the substrate. Consequently, cracks or fissures may take place adversely in the substrate.

In general, a substrate made of an LN single crystal or LT single crystal is an insulator, because it exhibits a volume resistivity of 10¹⁵ Ω·cm approximately.

In order to inhibit a substrate from being charged, the substrate can be enhanced in the electric conductivity. Lowering the volume resistivity of a substrate results in heightening the electric conductivity of the substrate. Consequently, even when a substrate, which exhibits a volumetric resistance falling in the aforementioned ranges, has undergone temperature changes, charges are less likely to arise on the substrate.

It is possible to lower the volumetric resistivity of a substrate easily or readily by subjecting the substrate to a reduction treatment as described below.

The substrate for surface acoustic wave element according to the present invention preferably has a thickness of 1 mm or less, more preferably, 0.5 mm or less, or much more preferably, 0.35 mm or less. When the thickness of a substrate falls in the ranges, it is possible to turn a surface acoustic wave element using such a substrate into a thin plate, and to cope with downsizing devices. Note that, in the present substrate, cracks are less likely to occur even when the thickness becomes thinner, because the present substrate is made from a single crystal having a uniform composition.

### Manufacturing Process for Substrate for Surface Acoustic Wave Element

A manufacturing process for surface acoustic wave element according to the present invention comprises a raw-material mixture preparation step, a raw-material mixture melting step, a single-crystal growth step, and a substrate fabrication step. The respective steps will be hereinafter explained.

### Raw-material Mixture Preparation Step

### Raw-material Mixture Preparation Step for Magnesium/Lithium Niobate Single Crystal

The present step is a step of preparing a raw-material mixture by mixing lithium carbonate (Li₂CO₃) making a lithium source, niobium pentoxide (Nb₂O₅) making a niobium source, and magnesium oxide (MgO) making a magnesium source with each other so as to satisfy following requirements (1) and (2).

(1) an atomic ratio between Li and Nb: 0.9048≤(Li/Nb)≤0.9685; and

(2) an MgO molar ratio with respect to a sum of LiNbO₃ and MgO assuming that LiNbO₃ is generated from Li₂CO₃ and Nb₂O₅: 0.01≤{MgO/(MgO+LiNbO₃)}≤0.09

The lithium carbonate (Li₂CO₃) making a lithium source, and the niobium pentoxide (Nb₂O₅) making a niobium source are mixed one another so that an atomic ratio between Li and Nb satisfies 0.9048≤(Li/Nb)≤0.9685. Moreover, it is assumed that the single-crystal chemical formula of lithium niobate, which is generated from the Li₂CO₃ and Nb₂O₅, is LiNbO₃ to determine an MgO mixing proportion. Thus, in a magnesium/lithium niobate single crystal to be generated, the Mg content proportion comes to be determined. To be concrete, the magnesium oxide (MgO) making a magnesium source is mixed so that an MgO molar ratio to a sum of LiNbO₃ and MgO satisfies 0.01≤{MgO/(MgO+LiNbO₃)}≤0.09.

When the “Li/Nb” value is 0.9048 or more, lithium atoms are not too less than niobium atoms. Accordingly, vacancy defects become less at the sites of lithium. When the lithium-site vacancy defects are less against the amount of Mg, Mg is gradually taken into a single crystal during its growing, so that the partition coefficient of Mg is likely to be one between the single crystal to be grown and the remaining melt. The “partition coefficient of Mg” is a ratio between an Mg concentration in the single crystal and another Mg concentration in the remaining melt. Consequently, the Mg content proportion is less likely to vary or fluctuate between the upper section and lower section in a single crystal which is obtained under a production condition in which the “Li/Nb” value is 0.9048 or more. In order to make the Mg content proportion not vary or fluctuate within a single crystal, a suitable “Li/Nb” value satisfies 0.9421≤(Li/Nb), more suitably, 0.9425≤(Li/Nb), or much more suitably, 0.9429≤(Li/Nb).

Moreover, when the “Li/Nb” value is 0.9685 or less, lithium atoms are less than niobium atoms. Accordingly, many vacancy defects arise at the sites of lithium. When the lithium-site vacancy defects are much against the amount of Mg, the number of remaining Mg atoms, which have not entered a single crystal during its growing, increases. As accompanied with the increase of remaining Mg atoms, an Mg concentration in the remaining melt is inhibited from becoming greater, so that the partition coefficient of Mg is likely to be one. In addition to this, when the “Li/Nb” value is 0.9685 or less, Mg is less likely to be segregated within a single crystal. Consequently, the resulting composition is likely to be uniform or homogeneous. Note that a suitable “Li/Nb” value satisfies (Li/Nb)≤0.9443, more suitably, (Li/Nb)≤0.9440, or much more suitably, (Li/Nb)≤0.9436.

When the {MgO/(MgO+LiNbO₃)} value is 0.01 or more, the partition coefficient of Mg is likely to be one between the single crystal to be grown and the remaining melt, so that the resulting composition is likely to be uniform or homogeneous on the upper section and lower section in a single crystal to be obtained. In particular, a suitable “MgO/(MgO+LiNbO₃)” value satisfies more suitably 0.03≤{MgO/(MgO+LiNbO₃)}, or much more suitably, 0.04≤{MgO/(MgO+LiNbO₃)}.

Moreover, when the “MgO/(MgO+LiNbO₃)” value is 0.09 or less, the partition coefficient of Mg is likely to be one similarly. Accordingly, the Mg is less likely to be segregated within a single crystal. Consequently, the resulting composition is likely to be uniform or homogeneous. Note that a suitable “MgO/(MgO+LiNbO₃)” value satisfies more suitably {MgO/(MgO+LiNbO₃)}<0.07, or much more suitably, {MgO/(MgO+LiNbO₃)}≤0.06.

Since the above-described production process produces a magnesium/lithium niobate single crystal so as to make the partition coefficient of Mg one, that is, since it produces the single crystal so as to make an Mg concentration in the melt, another Mg concentration in a single crystal and still another Mg concentration in the remaining melt identical with each other, a percent-by-mole Mg content proportion in the produced magnesium/lithium niobate single crystal becomes identical with a percent-by-mole MgO concentration in the raw-material mixture as a whole. In other words, a ratio, i.e., {MgO/(MgO+LiNbO₃)}, becomes exactly the same as another ratio, the Mg content proportion in the produced magnesium/lithium niobate single crystal.

Note that the aforementioned three raw materials are mixed with each other satisfactorily by a publicly-known method. For example, mixing by a ball mill is given as a method for mixing the raw materials. A mixing time is not limited at all especially, but the mixing is carried out properly for 10 hours approximately, for instance.

### Raw-material Mixture Preparation Step for Magnesium/Lithium Tantalate Single Crystal

The present step is a step of preparing a raw-material mixture by mixing lithium carbonate (Li₂CO₃) making a lithium source, tantalum pentoxide (Ta₂O₅) making a tantalum source, and magnesium oxide (MgO) making a magnesium source with each other so as to satisfy following requirements (3) and (4).

(3) an atomic ratio between Li and Ta: 0.9048≤(Li/Ta)≤0.9685; and

(4) an MgO molar ratio with respect to a sum of LiTaO₃ and MgO assuming that LiTaO₃ is generated from Li₂CO₃ and Ta₂O₅: 0.01≤{MgO/(MgO+LiTaO₃)}≤0.09.

The lithium carbonate (Li₂CO₃) making a lithium source, and the tantalum pentoxide (Ta₂O₅) making a tantalum source are mixed one another so that an atomic ratio between Li and Ta satisfies 0.9048≤(Li/Ta)≤0.9685. Moreover, it is assumed that the single-crystal chemical formula of lithium tantalate, which is generated from the Li₂CO₃ and Ta₂O₅, is LiTaO₃ to determine an MgO mixing proportion. Thus, in a magnesium/lithium tantalate single crystal to be generated, the Mg content proportion comes to be determined. To be concrete, MgO making a magnesium source is mixed so that an MgO molar ratio to a sum of LiTaO₃ and MgO satisfies 0.01≤{MgO/(MgO+LiTaO₃)}≤0.09.

When the “Li/Ta” value is 0.9048 or more, lithium atoms are not too less than tantalum atoms. Accordingly, vacancy defects become less at the sites of lithium. When the lithium-site vacancy defects are less against the amount of Mg, Mg is gradually taken into a single crystal during its growing, so that the partition coefficient of Mg is likely to be one between the single crystal to be grown and the remaining melt. Consequently, the Mg content proportion is less likely to vary or fluctuate between the upper section and lower section in a single crystal which is obtained under a production condition in which the “Li/Ta” value is 0.9048 or more. In order to make the Mg content proportion not vary or fluctuate within a single crystal, a suitable “Li/Ta” value satisfies 0.9421≤(Li/Ta), more suitably, 0.9425≤(Li/Ta), or much more suitably, 0.9429≤(Li/Ta).

Moreover, when the “Li/Ta” value is 0.9685 or less, lithium atoms are less than niobium atoms. Accordingly, many vacancy defects arise at the sites of lithium. When the lithium-site vacancy defects are much against the amount of Mg, the number of remaining Mg atoms, which have not entered a single crystal during its growing, increases. As accompanied by the increase of remaining Mg atoms, an Mg concentration in the remaining melt is inhibited from becoming greater, so that the partition coefficient of Mg is likely to be one. In addition to this, when the “Li/Ta” value is 0.9685 or less, Mg is less likely to be segregated within a single crystal. Consequently, the resulting composition is likely to be uniform or homogeneous. Note that a suitable “Li/Ta” value satisfies (Li/Ta)≤0.9443, more suitably, (Li/Ta)≤0.9440, or much more suitably, (Li/Ta)≤0.9436.

When the “MgO/(MgO+LiTaO₃)” value is 0.01 or more, the partition coefficient of Mg is likely to be one between the single crystal to be grown and the remaining melt, so that the resulting composition is likely to be uniform or homogeneous on the upper section and lower section in a single crystal to be obtained. In particular, in order to make the Mg content proportion not vary or fluctuate in the resultant single crystal, a suitable “MgO/(MgO+LiTaO₃)” value satisfies 0.03≤{MgO/(MgO+LiTaO₃)}, or more suitably, 0.04≤{MgO/(MgO+LiTaO₃)}.

Moreover, when the “MgO/(MgO+LiTaO₃)” value is 0.09 or less, besides the partition coefficient of Mg being likely to be one similarly, Mg is less likely to be segregated within a single crystal. Consequently, the resulting composition is likely to be uniform or homogeneous. In particular, a suitable “MgO/(MgO+LiTaO₃)” value is {MgO/(MgO+LiTaO₃)}<0.07, or more suitably, {MgO/(MgO+LiTaO₃)}≤0.06.

Since the above-described production process produces a magnesium/lithium tantalate single crystal so as to make the partition coefficient of Mg one, that is, since it produces the single crystal so as to make an Mg concentration in the melt, another Mg concentration in a single crystal and still another Mg concentration in the remaining melt identical with each other, a percent-by-mole Mg content proportion in the produced magnesium/lithium tantalate single crystal becomes identical with a percent-by-mole MgO concentration in the raw-material mixture as a whole. In other words, a ratio, i.e., {MgO/(MgO+LiTaO₃)}, becomes exactly the same as another ratio, the Mg content proportion in the produced magnesium/lithium tantalate single crystal.

Note that the aforementioned three raw materials are mixed with each other satisfactorily by a publicly-known method. For example, mixing by a ball mill is given as a method for mixing the raw materials. A mixing time is not limited at all especially, but the mixing is carried out properly for 10 hours approximately, for instance.

Conventionally, a single crystal, which is grown by mixing and then melting predetermined raw materials including Mg by a Czochralski method, for instance, has been associated with such a problem that the partition coefficient of Mg is not one between the single crystal to be grown and the remaining melt. That is, an Mg content proportion has become different in the melt (i.e., the raw materials), and in the grown single crystal. Consequently, during the process of pulling up a single crystal, an Mg concentration gradient occurs between the melt (i.e., the raw materials) and the grown single crystal. Therefore, between part, which is pulled up first, and another part, which is pulled up later, the compositions have not been even or homogeneous in the grown single crystal. That is, the compositions have become uneven or inhomogeneous between the upper section and the lower section in the resulting single crystal.

In the production process according to the present invention, an attention is focused on the ternary-system raw-material composition comprising a lithium source, niobium source and magnesium source, or the ternary-system raw-material composition comprising a lithium source, tantalum source and magnesium source, so as to make the partition coefficient of Mg one between the resulting single crystal and the remaining melt by specifying mixing proportions of the respective raw materials. In other words, the partition coefficient of Mg is made one virtually by utilizing a raw-material mixture, in which the three kinds of the compounds are mixed with each other as a starting material so as to satisfy requirements (1) and (2) as aforementioned, or requirements (3) and (4) as aforementioned. The content proportions of Mg in the upper section and lower section of the resultant single crystal are made uniform or homogenous one another by making the partition coefficient of Mg one virtually. Therefore, in accordance with the present production process, a uniform or homogenous magnesium/lithium niobate single crystal or magnesium/lithium tantalate single crystal is obtained by mixing the three kinds of the raw-material compounds in the specific proportions at the raw-material mixture preparation step.

Moreover, after the respective raw materials have been mixed with each other to prepare a raw-material mixture, the raw-material mixture may be calcined and then subjected to the next step, namely, the raw-material mixture melting step. If such is the case, the production process according to the present invention further comprises a raw-material mixture calcination step of calcining the prepared raw-material mixture after the raw-material mixture preparation step and before the raw-material mixture melting step. A calcination temperature at the raw-material mixture calcination step is not limited at all especially. The calcination is carried out satisfactorily in a range of from 900° C. to 1,200° C., for instance. In addition, the calcination is usually carried out once, but is even carried out multiple times separately or one after another, if needed. A calcination time is not limited at all especially, either. The calcination is carried out properly for 10 hours approximately.

### Raw-Material Mixture Melting Step

The present step is a step of melting the raw-material mixture to make it into a raw-material mixture melt. A method of melting the raw-material mixture is not limited at all especially. In the case of an LN single crystal, the raw-material mixture is put into a crucible made of platinum, and is then melted satisfactorily by high-frequency induction heating, for instance. The raw-material mixture is melted properly at a temperature of from 1,260° C. to 1,350° C., for instance. In the case of an LT single crystal, the raw-material mixture is put into a crucible made of iridium, and is then melted satisfactorily by high-frequency induction heating, for instance. The raw-material mixture is melted properly at a temperature of from 1,650° C. to 1,710° C., for instance.

### Single-Crystal Growth Step

The present step is a step of growing a magnesium/lithium niobate single crystal or magnesium/lithium tantalate single crystal by immersing a seed crystal into the raw-material mixture melt obtained at the raw-material mixture melting step, and then pulling up the seed crystal therefrom. Note herein that the seed crystal to be employed satisfactorily is a piece of a lithium niobate single crystal or lithium tantalate single crystal, which is cut out in the orientation of a targeted axis. The magnesium/lithium niobate single crystal or magnesium/lithium tantalate is grown by immersing this seed crystal into the raw-material mixture melt and then pulling it up therefrom. Conditions under which the seed crystal is pulled up are not limited at all especially. The seed crystal is pulled up satisfactorily at such a pull-up speed as from 1 to 10 mm/hr while revolving it at a speed of from 5 to 20 rpm, for instance.

### Substrate Fabrication Step

The substrate fabrication step is a step of fabricating a substrate from the magnesium/lithium niobate single crystal or magnesium/lithium tantalate single crystal obtained at the single-crystal growth step. The substrate fabrication step includes a cutting step, and a polishing step. The substrate fabrication step further includes a reduction treatment step, for instance, if needed.

The cutting step is a step of cutting from out of the single crystal a plate having a predetermined thickness in a direction that makes the orientation of a targeted axis. The single crystal is cut satisfactorily using a commercially available cutting machine, such as a multi-wire saw. The cut thickness is not limited at all especially. The single crystal is cut properly to a desired thickness substantially, and is then grounded appropriately to the desired thickness at the following polishing step. Cutting conditions for the cutting machine are not limited at all especially, either. In the case of a multi-wire saw, the single crystal is cut effectively so as to have a desired thickness using a wire whose diameter is from 0.1 mm to 0.15 mm, and at a cutting speed of from 5.0 mm/hr to 10.0 mm/hr.

The polishing step is a step of mirror polishing the plate, which has been cut out at the cutting step, on one of the opposite faces or on both of the opposite faces. The mirror polishing is carried out satisfactorily using a common polishing machine. For example, a method of mirror polishing, which is used preferably, is a mechanochemical polishing system by colloidal silica. The substrate, which is mirror polished, has a thickness of 1 mm or less preferably, more preferably, 0.5 mm or less, or much more preferably, 0.35 mm or less.

Moreover, since the magnesium/lithium niobate single crystal or magnesium/lithium tantalate single crystal, which is obtained by the production process according to the present invention, suffers less from the segregation of Mg and has an even or homogenous composition, cracks occur less at the time of cutting and polishing. Therefore, the present production process provides the means to obtain in a high yield a substrate for surface acoustic wave element, the substrate comprising the magnesium/lithium niobate single crystal or magnesium/lithium tantalate single crystal whose crystalline composition is even or homogenous, and in which cracks occur less.

The reduction treatment step is a step of reducing the fabricated substrate. A method of the reduction treatment is not limited at all especially as far as it is a reduction treatment method for inhibiting the pyroelectric effect. For example, it is possible to give a reduction treatment method in which a substrate is reduced by the following steps: accommodating the substrate comprising the magnesium/lithium niobate single crystal or magnesium/lithium tantalate single crystal, and a reducing agent including an alkali metal compound in a processing apparatus; and retaining the interior of the processing apparatus at 200° C. or more and at a temperature of less than a Curie temperature of the single crystal constituting the substrate while placing the interior under reduced pressure.

The alkali metal compound constituting a reducing agent evaporates under predetermined conditions, and then turns into a vapor whose reducing power is high. The substrate is exposed to this vapor, so that it is reduced sequentially starting at the surfaces. Moreover, keeping supplying the reducing agent enables the reduction reaction to progress continuously, and accordingly makes it possible to uniformly or homogenously reduce the entire substrate.

The resistance of the substrate is declined by the reduction. Hence, the reduced substrate is of high electric conductivity. Accordingly, the substrate is less likely to produce electric charges even when the temperature changes. Moreover, if electric charges should have occurred on the surfaces of the substrate, the electric charges are removable because they undergo self-neutralization quickly. The reduced substrate is not only easy to handle but also safe because it is less likely to be charged electrically. Consequently, using this reduced substrate enables manufacturers to constitute surface acoustic wave elements in which defects or flaws resulting from static electricity are less likely to occur at the time of storage and even during use or service.

Moreover, when the alkali metal compound, which reacts relatively mildly, is used as a reducing agent, the reducing agent is easy to handle and is highly safe as well. In addition, a degree of the reduction in the substrate is controlled by suitably adjusting the following: the type, employment amount and arranged form of a reducing agent; the temperature and vacuum degree inside a processing container; and the processing time.

When a substrate is fabricated from the magnesium/lithium niobate single crystal, a reduction treatment temperature for the substrate is desirably from 200° C. or more to 1,000° C. or less. Since the magnesium/lithium niobate single crystal exhibits a Curie temperature at around 1,200° C., it may lose the piezoelectricity adversely when being exposed to high temperatures which are higher than the Curie temperature.

When a substrate is fabricated from the magnesium/lithium tantalate single crystal, a reduction treatment temperature for the substrate is desirably from 200° C. or more to 600° C. or less. Since the magnesium/lithium tantalate single crystal exhibits a Curie temperature at around 700° C., it may lose the piezoelectricity adversely when being exposed to high temperatures which are higher than the Curie temperature. Hence, a substrate fabricated from the magnesium/lithium tantalate single crystal is treated desirably at such a relatively low temperature as 600° C. or less. Note that, when an alkali metal compound exhibiting a high reducing property is used, it is possible to sufficiently reduce the entire substrate even at a low temperature of 600° C. or less.

The magnesium/lithium niobate single crystal or magnesium/lithium tantalate single crystal is inhibited from being charged electrically by carrying out the reduction treatment at a relatively low temperature without ever imparting the piezoelectricity.

The substrate is reduced desirably under such a reduced pressure as from 133×10⁻¹ Pa to from 133×10⁻⁷ Pa, or more desirably, under such a reduced pressure as from 133×10⁻² Pa to from 133×10⁻⁶ Pa. The alkali metal compound is satisfactorily turned into a vapor with a high reducing power even under a relatively low-temperature condition by making a vacuum degree higher within a processing container.

The substrate is reduced preferably until it exhibits a volume resistivity of 9.9×10¹² Ω·cm or less, more preferably, until it exhibits a volume resistivity of 9.9×10¹¹ Ω·cm or less, or more much preferably, until it exhibits a volume resistivity of 9.9×10¹⁰ Ω·cm or less.

Moreover, a lithium-containing compound is employed desirably for the alkali metal compound used as a reducing agent. The oxygen in the magnesium/lithium tantalate single crystal, or the oxygen in the magnesium/lithium niobate single crystal exhibits a high bonding force to lithium. Accordingly, in the reduction treatment, the oxygen is likely to be emitted in a state of being bonded to lithium, namely, in the form of lithium oxide. Consequently, the lithium concentration in the single crystal decreases to change the ratio between lithium and tantalum or the ratio between lithium and niobium in the single crystal. As a result, the single crystal may adversely suffer from the changing piezoelectricity. When employing a lithium-containing compound for the alkali metal compound used as a reducing agent, lithium atoms supplied from the reducing agent reacts with oxygen within the single crystal. Therefore, lithium atoms within the single crystal are less likely to be emitted. Hence, the ratio between lithium and tantalum, or the ratio between lithium and niobium within the single crystal is inhibited from changing to result in lowering the piezoelectricity.

In addition, when a lithium compound is employed for the alkali metal compound used as a reducing agent, and even when lithium atoms supplied from the reducing agent have been intermingled inadvertently into the single crystal, any major change is less likely to appear in the structure of the single crystal, because lithium is one of the intrinsic constituent elements of the single crystal.

Moreover, it is also preferable to adopt an embodiment in which the substrate is reduced under such conditions that a reducing agent comprising the alkali metal compound is used and the reducing agent and substrate are disposed independently of one another or the substrate is buried in the reducing agent. If such is the case, it is possible to use, as the reducing agent, the alkali metal compound in the form of a powder or pellet, and the like. This embodiment is likely to be executed or implemented, because a powder or pellet of the alkali metal compound can be employed as it is. In addition, when the substrate is buried in the reducing agent, the reducing agent is in contact with the substrate on the surfaces in a highly-concentrated manner. Hence, the substrate is reduced in a more facilitated manner.

In addition, when a solution, in which the alkali metal compound is dissolved or dispersed in a solvent, is used as a reducing agent, it is possible to adopt another embodiment in which the substrate is reduced under such a condition that the reducing agent and substrate are disposed independently of one another, or the substrate is immersed in the reducing agent, or the reducing agent is painted or coated on a surface of the substrate. Heating a solution, in which the alkali metal compound is dissolved or dispersed in an organic solvent, generates an organic gas. Accordingly, the reactivity is enhanced between the alkali metal compound and the substrate by filling up a vapor of the alkali metal compound into the organic gas. Thus, the entire substrate is reduced without any unevenness. Moreover, when the substrate is immersed in the solution, or when the solution is painted or coated on a surface of the substrate, the reducing agent is in contact with the substrate on the surfaces or on one of the surfaces in a highly-concentrated manner. Hence, the substrate is reduced in a more facilitated manner.

Having been described so far are some of the embodiment modes of the substrate for acoustic surface wave element according to the present invention and the production process for the same. However, the present invention is not at all limited to the above-described embodiment modes. That is, it is possible to execute or implement the present invention in various modes that have undergone modifications or improvements, and the like, which a person having ordinary skill in the art can think of, within a range not departing from the gist or spirit of the present invention.

### EXAMPLES

First of all, a magnesium/lithium niobate single crystal to be used in the present invention was produced variously based on the above-described embodiment modes. Moreover, a lithium niobate single crystal was produced as a comparative example.

### Production “A” for Magnesium/Lithium Niobate Single Crystal

Four magnesium/lithium niobate single crystals were produced. The produced magnesium/lithium niobate single crystals exhibited an “Li/Nb” value of from 0.9421 to 0.9443, and had an Mg content proportion of 5.15% by mole.

Four raw-material mixtures were prepared by mixing Li₂CO₃, Nb₂O₅ and MgO with each other so as to make the “Li/Nb” value the following values: 0.9421, 0.9425, 0.9440, and 0.9443; and additionally so as to make an MgO molar ratio 0.0515 to a sum of LiNbO₃ and MgO (i.e., the “MgO/(MgO+LiNbO₃)” value). The prepared raw-material mixtures were calcined at 1,000° C. for 10 hours, and were thereafter put in a crucible made of platinum, respectively. Then, the raw-material mixtures were melted by high-frequency induction heating. The melting temperature was 1,300° C. A seed crystal was immersed into each of the resulting raw-material mixture melts, and was then pulled up at a pull-up speed of 5 mm/hr while revolving it at a speed of 10 rpm. Thus, single crystals, which had a diameter of about 80 mm and a length of about 60 mm, were obtained. The used seed crystal was an LN single crystal which had been cut out in the orientation of a targeted axis. The thus obtained magnesium/lithium niobate single crystals were numbered #11 through #14.

### Evaluation on Produced Magnesium/Lithium Niobate Single Crystal

Each of the produced magnesium/lithium niobate single crystals #11 through #14 were subjected to cutting to cut out plates from the sites that existed away from the upper end by 5 mm, 30 mm, and 60 mm in each of the single crystals. The cut-out plates had a thickness of 1 mm. Note that a side, which was the most closest to the seed crystal in the resulting single crystals, namely, an end, which was on a side having been pulled up firstly, was labeled an “upper end.” Then, each of the plates was mirror polished on the opposite faces to fabricate wafers for measurement. That is, three measurement wafers were fabricated for each of the magnesium/lithium niobate single crystals, and were classified into an upper section, a middle section and a lower section depending on from where they were cut out. The thus fabricated measurement wafers were employed to carry out various measurements and analyses. The measurements and analyses will be hereinafter detailed one by one.

### (I) Calculation of Partition Coefficient of Mg

In order to find a partition coefficient of Mg between the obtained magnesium/lithium niobate single crystals and the remaining melts, an Mg content proportion in each of the fabricated wafers, and another Mg content proportion in each of the remaining melts were analyzed by inductively coupled plasma atomic emission spectroscopy (or ICP-AES). Then, an averaged value of the Mg content proportions in the three wafers was found for each of the magnesium/lithium niobate single crystals. Partition coefficients of Mg were found by dividing the resultant averaged values by the values of Mg content proportions in the respective remaining melts.

### (II) Crystal-Growing Success Yield

An investigation was conducted to examine to what proportional extent cracks occurred upon producing each of the magnesium/lithium niobate single crystals having compositions as described above. Each of the magnesium/lithium niobate single crystals having the compositions was produced in a quantity of 20 by the above-described production process, in order to calculate a proportion of the single crystals, in which no cracks occurred, to designate the proportion a “percentage crystal-growing success yield.” That is, the crystal-growing success yield is a quotient, which is found by dividing the number of times the single crystals were grown successfully by the number of total times the single crystals were grown, and is expressed in percentages.

Table 1 collectively shows results of the measurements as described above in items (I) and (II).

TABLE 1

| | #11 | #12 | #13 | #14 |
|---|---|---|---|---|
| “Li/Nb” in Melt | 0.9421 | 0.9425 | 0.9440 | 0.9443 |
| Mg in Melt | 5.15 | 5.15 | 5.15 | 5.15 |
| (% by mole) | | | | |
| Mg in Single | 5.14 | 5.15 | 5.15 | 5.16 |
| Crystal's Upper | | | | |
| Section | | | | |
| (% by mole) | | | | |
| Mg in Single | 5.14 | 5.14 | 5.16 | 5.17 |
| Crystal's Middle | | | | |
| Section | | | | |
| (% by mole) | | | | |
| Mg in Single | 5.13 | 5.14 | 5.15 | 5.17 |
| Crystal's Lower | | | | |
| Section | | | | |
| (% by mole) | | | | |
| Mg in Remaining | 5.15 | 5.15 | 5.17 | 5.14 |
| Melt | | | | |
| (% by mole) | | | | |
| Distribution | 0.997 | 0.999 | 1.002 | 1.003 |
| Coefficient of Mg | | | | |
| Crystal-growing | 84 | 91 | 90 | 86 |
| Success Yield | | | | |
| (%) | | | | |

According to Table 1, all of the magnesium/lithium niobate single crystals #11 through #14, in which the “Li/Nb” values were 0.9421, 0.9425, 0.9440 and 0.9443, came to exhibit the partition coefficient of Mg, which was virtually one, respectively. This indicates that the Mg content proportion in the single crystals were virtually coincident with that in the remaining melts. That is, the single crystals came to have a composition that was uniform or homogeneous between the upper section and the lower section.

Moreover, in the magnesium/lithium niobate single crystals #11 through #14, cracks hardly occurred. Thus, the crystal-growing success yields were found to be high.

In addition, from the viewpoint of crystalline uniformity or homogeneity, the “Li/Nb” value was found to more preferably fall in a range of from 0.9425 to 0.9440. It is speculated that, as the single crystals become more uniform or homogeneous, they exhibit a higher thermal conductivity as well.

As described above, it was ascertained that, when a magnesium/lithium niobate single crystal to be used in the present invention is produced by mixing the raw materials with each other so that the “Li/Nb” value makes 0.9421≤(Li/Nb)≤0.9443 and the “MgO/(MgO+LiNbO₃)” value satisfies 0.0515, the resulting magnesium/lithium niobate single crystal makes a single crystal whose upper section, middle section and lower section have a uniform or homogeneous composition.

Note that it is possible to maintain that the same results as described above are expected for a magnesium/lithium tantalate single crystal as well, although the results described above were observed about a magnesium/lithium niobate single crystal.

Moreover, the outcomes given in Table 1 made the inventors ascertain that, when the raw-material mixtures were prepared by mixing the Li₂CO₃, Nb₂O₅ and MgO with each other so as to make the “MgO/(MgO+LiNbO₃)” value 0.0515, the molar Mg percentages in the melts (i.e., the raw-material mixtures) were virtually 5.15; and that the molar Mg percentages in the upper section, middle section and lower section of the thus obtained magnesium/lithium niobate single crystals were virtually identical values with each other. From the ascertainment, it was found that a value “MgO/(MgO+LiNbO₃)” expressed in percentage, namely, a percent-by-mole MgO concentration in a raw-material mixture, becomes identical with a percent-by-mole Mg content proportion in the resulting magnesium/lithium niobate single crystal.

### Production for Magnesium/Lithium Niobate Single Crystal Subjected to Reduction Treatment

Nine magnesium/lithium niobate single crystals were produced. The produced magnesium/lithium niobate single crystals exhibited an “Li/Nb” value of from 0.9433, and had an Mg content proportion of from 1% by mole to 9% by mole. Moreover, a lithium niobate single crystal was produced. The produced lithium niobate single crystal was free from Mg, and exhibited an “Li/Nb” value of 0.9433.

Ten raw-material mixtures were prepared by mixing Li₂CO₃, Nb₂O₅ and MgO with each other so as to make the “Li/Nb” value 0.9443; and additionally so as to make an MgO molar ratio the following values to a sum of LiNbO₃ and MgO (i.e., the “MgO/(MgO+LiNbO₃)” value): 0, 0.01, 0.02, 0.03, 0.04, 0.05, 0.06, 0.07, 0.08 and 0.09. The prepared raw-material mixtures were calcined at 1,000° C. for 10 hours, and were thereafter put in a crucible made of platinum, respectively. Then, the raw-material mixtures were melted by high-frequency induction heating. The melting temperature was 1,300° C. A seed crystal was immersed into each of the resulting raw-material mixture melts, and was then pulled up at a pull-up speed of 5 mm/hr while revolving it at a speed of 10 rpm. Thus, single crystals, which had a diameter of about 100 mm and a length of about 60 mm, were obtained. The thus obtained single crystals were numbered #20 through #29. The used seed crystal was an LN single crystal which had been cut out in the orientation of a targeted axis. Note that the “MgO/(MgO+LiNbO₃)” value expressed in percentage, will be hereinafter designated as a “percent-by-mole MgO concentration.”

The produced lithium niobate single crystal #20, and the produced magnesium/lithium niobate single crystals #21 through #29 were subjected to cutting to cut out plates from the sites that existed away from the upper end by 5 mm and 60 mm in each of the single crystals. The cut-out plates had a thickness of about 0.35 mm. Note that a side, which was the most closest to the seed crystal in the resulting single crystals, namely, an end, which was on a side having been pulled up firstly, was labeled an “upper end”; and another side, which was most away off from the seed crystal, namely, another end across from the upper end, was labeled a “lower end.” That is, for each of the lithium niobate single crystal and magnesium/lithium niobate single crystals, two plates, namely, an upper-section plate and a lower-section plate, were fabricated, depending on the sites from which they were cut out.

A reduction treatment apparatus was used to carry out a reduction treatment to each of the thus obtained plates. The reduction treatment apparatus comprised a processing container, a heater, and a vacuum pump; and was constructed so that piping was connected with the processing container at one of the opposite ends, and was further connected with the vacuum pump at the other one of the opposite ends. Through the piping connected as above, gases within the processing container were exhausted.

The respective plates, and a lithium chloride powder serving as a reducing agent were accommodated in the processing container. The plates were arranged in a cassette case made of quartz so that they were separated away from each other at intervals of about 5 mm. The lithium chloride powder was accommodated inside a petri dish made of quartz glass independently of the plates. Note that the lithium chloride powder was accommodated in an amount of 100 g. The heater was arranged so as to surround the processing chamber around the circumference.

An exemplary flow how the reduction treatment apparatus carried out the reduction treatment will be hereinafter explained. First of all, a vacuum atmosphere of 1.33 Pa approximately was produced within the processing container by the vacuum pump. Subsequently, the processing container was heated by the heater to raise the temperature within the processing container to 550° C. in three hours. When the temperature within the processing container reached 550° C., the condition was retained for 18 hours. Thereafter, the heater was turned off to naturally cool the interior of the processing container. Thus, the plates, to which the reduction treatment had been carried out, were obtained.

One of the opposite faces of the plates, to which the reduction treatment had been carried out, was mirror polished to obtain a wafer for measurement. The measurement wafers had a diameter of ϕ 100 mm (or ϕ 4 inches), and a thickness of 0.35 mm; and they made a 128-deg. Y-cut X-propagation substrate, respectively. Note that, in the final polishing, a system of mechanochemical polishing by colloidal silica was adopted.

The wafers, which had been prepared from the magnesium/lithium niobate single crystals, had a white color before the reduction treatment, and had a blue-gray color after the reduction treatment. Moreover, since the white color or blue-gray color of the wafers was uniform or homogeneous in each of the wafers as a whole, it was understood at a glance that magnesium, the additive element, was added uniformly or homogenously.

### Evaluation on Produced and Reduced Magnesium/Lithium Niobate Single Crystal

### (III) Measurement of Curie Temperature

Curie temperatures in the upper-section wafers and lower-section wafers of the single crystals were measured by differential thermal analyzer (or DTA). The Curie temperatures were measured at five locations in total, namely, at the central site of the wafers and at four locations in the circumferential site on the inner side by 5 mm across from the wafers' edge. Since the temperatures measured at the five locations were virtually identical with each other, Table 2 recites the temperatures, which were measured at the central site in the respective wafers, as the Curie temperatures. Moreover, each of the single crystals was computed for the difference between the Curie temperature in the upper-section wafer and that in the lower-section wafer. Note that the values measured at the central site in the respective wafers were used to compute the differences between the Curie temperatures.

### (IV) Flawless Wafer Yield

The “flawless wafer yield” was a percentage expression of a number of flawless products, which were deserved to be a final product, among all the products, which were cut out in a quantity of 100 pieces from the single crystals as a plate with a thickness of 0.6 mm. The “flawless product” means that the wafers, which had undergone the reduction, washing and polishing steps, were found to be free from any breakages, chip-offs or cracks, and the like, so that they were judged to be an employable product, respectively.

### (V) Volume Resistivity

“DSM-8103” produced by TOA DKK Co., Ltd. was used to measure volume resistivities of the single crystals.

Table 2 collectively shows results of the measurements as described above in items (III) through (V).

TABLE 2

| | #20 | #21 | #22 | #23 | #24 | #25 | #26 | #27 | #28 | #29 |
|---|---|---|---|---|---|---|---|---|---|---|
| “Li/Nb” in | 0.9433 | 0.9433 | 0.9433 | 0.9433 | 0.9433 | 0.9433 | 0.9433 | 0.9433 | 0.9433 | 0.9433 |
| Melt | | | | | | | | | | |
| MgO | 0.00 | 1.00 | 2.00 | 3.00 | 4.00 | 5.00 | 6.00 | 7.00 | 8.00 | 9.00 |
| Concentration | | | | | | | | | | |
| (% by mole) | | | | | | | | | | |
| Curie Temp. in | 1130.5 | 1155.6 | 1178.0 | 1197.8 | 1204.3 | 1211.1 | 1211.5 | 1209.0 | 1205.7 | 1205.8 |
| Upper Section | | | | | | | | | | |
| (° C.) | | | | | | | | | | |
| Curie Temp. in | 1130.4 | 1156.5 | 1178.0 | 1193.6 | 1206.2 | 1211.3 | 1211.6 | 1209.6 | 1204.7 | 1200.5 |
| Lower Section | | | | | | | | | | |
| (° C.) | | | | | | | | | | |
| Difference | 0.1 | 0.9 | 0 | 4.2 | 1.9 | 0.2 | 0.1 | 0.6 | 1.0 | 5.3 |
| between Upper | | | | | | | | | | |
| Section and | | | | | | | | | | |
| Lower | | | | | | | | | | |
| Section's | | | | | | | | | | |
| Curie Temps. | | | | | | | | | | |
| Flawless | 97.3 | 94.6 | 94.7 | 94.5 | 95.7 | 97.5 | 97.1 | 89.2 | 63.2 | 45.4 |
| Wafer Yield | | | | | | | | | | |
| (%) | | | | | | | | | | |
| Volume | 2.23 × | 3.13 × | 4.00 × | 3.33 × | 2.35 × | 2 . 51 × | 4.15 × | 5.11 × | 4.35 × | 6.21 × |
| Resistivity | 10⁹ | 10⁹ | 10⁹ | 10⁹ | 10⁹ | 10⁹ | 10⁹ | 10⁹ | 10⁹ | 10⁹ |
| (Ω · cm) | | | | | | | | | | |

As Table 2 shows, the differences between the Curie temperatures in the upper-section wafers and those in the lower-section wafers were very minute in the respective magnesium/lithium niobate single crystals #21 through #29 whose melts exhibited such an atomic ratio between Li and Nb as (Li/Nb)=0.9433, and whose percent-by-mole MgO concentrations were from 1% by mole to 9% by mole. Accordingly, each of the magnesium/lithium niobate single crystals #21 through #29 was found out to be a uniform or homogeneous single crystal. Moreover, the respective magnesium/lithium niobate single crystals #21 through #29 were found out to exhibit a Curie temperature of from 1, 150° C. or more to 1,215° C. or less, although the lithium niobate single crystal #20 exhibited a Curie temperature of 1,130° C.

From a viewpoint of the flawless wafer yield, the percent-by-mole MgO concentration was found out to fall preferably in a range of from 1% by mole or more to less than 7% by mole, more preferably, from 1% by mole or more to 6% by mole or less, much more preferably, from 4% by mole or more to 6% by mole or less.

Note herein that a percent-by-mole MgO concentration should be identical with a percent-by-mole Mg content proportion in a magnesium/lithium niobate single crystal. Therefore, it is possible to say that the percent-by-mole MgO concentration indicates the percent-by-mole Mg content proportion.

Note that, although Tables 1 and 2 give the results observed about the magnesium/lithium niobate single crystals, it is possible to speculate rationally that similar results are expected from magnesium/lithium tantalate crystals as well because a magnesium/lithium niobate single crystal and magnesium/lithium tantalate single crystal have crystal structures that are similar to one another.

### Production “B” for Magnesium/Lithium Niobate Single Crystal

Fourteen magnesium/lithium niobate single crystals were produced. The produced manganese/lithium niobate single crystals exhibited an “Li/Nb” value of from 0.8868 to 0.9802, and had an Mg content proportion of 3% by mole.

Fourteen raw-material mixtures were prepared by mixing Li₂CO₃, Nb₂O₅ and MgO with each other so as to make the “Li/Nb” value the following values: 0.8868, 0.9048, 0.9231, 0.9305, 0.9380, 0.9417, 0.9421, 0.9429, 0.9436, 0.9444, 0.9455, 0.9531, 0.9685, and 0.9802; and additionally so as to make an MgO molar ratio 0.03 to a sum of LiNbO₃ and MgO (i.e., the “MgO/(MgO+LiNbO₃)” value). The prepared raw-material mixtures were calcined at 1,000° C. for 10 hours, and were thereafter put in a crucible made of platinum, respectively. Then, the raw-material mixtures were melted by high-frequency induction heating. The melting temperature was 1,300° C. A seed crystal was immersed into each of the resulting raw-material mixture melts, and was then pulled up at a pull-up speed of 5 mm/hr while revolving it at a speed of 10 rpm. Thus, single crystals, which had a diameter of about 80 mm and a length of about 60 mm, were obtained. The used seed crystal was an LN single crystal which had been cut out in the orientation of a targeted axis. The thus obtained magnesium/lithium niobate single crystals were numbered #31 through #44.

After subjecting each of the magnesium/lithium niobate single crystals #31 through #44 to a reduction treatment in the same manner as described for the magnesium/lithium niobate single crystals #21 through #29, wafers for measurement were fabricated likewise. Then, measurements were carried out to the measurement wafers in the same manner as described above in items (III) through (V) to find the Curie temperatures, flawless wafer yields and volumetric resistivities of the respective magnesium/lithium niobate single crystals #31 through #44. Table 3 shows results of the measurements all together.

TABLE 3

| | #31 | #32 | #33 | #34 | #35 | #36 | #37 | #38 | #39 | #40 |
|---|---|---|---|---|---|---|---|---|---|---|
| “Li/Nb” in | 0.8868 | 0.9048 | 0.9231 | 0.9305 | 0.9380 | 0.9417 | 0.9421 | 0.9429 | 0.9436 | 0.9444 |
| Melt | | | | | | | | | | |
| MgO | 3.00 | 3.00 | 3.00 | 3.00 | 3.00 | 3.00 | 3.00 | 3.00 | 3.00 | 3.00 |
| Concentration | | | | | | | | | | |
| (% by mole) | | | | | | | | | | |
| Curie Temp. in | 1178.4 | 1179.1 | 1186.0 | 1189.8 | 1190.2 | 1190.3 | 1192.0 | 1195.0 | 1197.0 | 1199.3 |
| Upper Section | | | | | | | | | | |
| (° C.) | | | | | | | | | | |
| Curie Temp. in | 1173.5 | 1173.7 | 1182.4 | 1186.2 | 1185.9 | 1186.1 | 1189.4 | 1191.1 | 1193.2 | 1195.3 |
| Lower Section | | | | | | | | | | |
| (° C.) | | | | | | | | | | |
| Difference | 4.9 | 5.4 | 3.6 | 3.6 | 4.3 | 4.2 | 2.6 | 3.9 | 3.8 | 4.0 |
| between Upper | | | | | | | | | | |
| Section and | | | | | | | | | | |
| Lower | | | | | | | | | | |
| Section's | | | | | | | | | | |
| Curie Temps. | | | | | | | | | | |
| Flawless | 68.3 | 82.3 | 80.1 | 84.5 | 89.0 | 89.2 | 93.4 | 96.4 | 95.2 | 94.5 |
| Wafer Yield | | | | | | | | | | |
| (%) | | | | | | | | | | |
| Volume | 3.34 × | 3.38 × | 4.04 × | 5.33 × | 6.23 × | 6.02 × | 5.73 × | 5.50 × | 4.93 × | 2.39 × |
| Resistivity | 10⁹ | 10⁹ | 10⁹ | 10⁹ | 10⁹ | 10⁹ | 10⁹ | 10⁹ | 10⁹ | 10⁹ |
| (Ω · cm) | | | | | | | | | | |

| | #41 | #42 | #43 | #44 |
|---|---|---|---|---|
| “Li/Nb” in | 0.9455 | 0.9531 | 0.9685 | 0.9802 |
| Melt | | | | |
| MgO | 3.00 | 3.00 | 3.00 | 3.00 |
| Concentration | | | | |
| (% by mole) | | | | |
| Curie Temp. in | 1202.3 | 1205.3 | 1206.8 | 1211.2 |
| Upper Section | | | | |
| (° C.) | | | | |
| Curie Temp. in | 1197.4 | 1201.2 | 1200.6 | 1204.3 |
| Lower Section | | | | |
| (° C.) | | | | |
| Difference | 4.9 | 4.1 | 6.2 | 6.9 |
| between Upper | | | | |
| Section and | | | | |
| Lower | | | | |
| Section's | | | | |
| Curie Temps. | | | | |
| Flawless | 89.7 | 83.7 | 80.4 | 60.8 |
| Wafer Yield | | | | |
| (%) | | | | |
| Volume | 4.32 × | 5.31 × | 6.91 × | 6.23 × |
| Resistivity | 10⁹ | 10⁹ | 10⁹ | 10⁹ |
| (Ω · cm) | | | | |

It was found out from the results shown in Table 3 that the flawless wafer yield was 80% or more when the magnesium/lithium niobate single crystals #32 through #43 were prepared. That is, it was found out that the flawless wafer yield is high when the atomic ratio between Li and Nb satisfies 0.9048≤(Li/Nb)≤0.9685. It is believed that the resultant flawless wafer yield is affected by the uniformity or homogeneity of single crystal. It is believed conversely that a high flawless wafer yield signifies that the uniformity or homogeneity of single crystal is high.

### Production “C” for Magnesium/Lithium Niobate Single Crystal

Fourteen magnesium/lithium niobate single crystals were produced. The produced magnesium/lithium niobate single crystals exhibited an “Li/Nb” value of from 0.8868 to 0.9802, and had an Mg content proportion of 5% by mole.

Fourteen raw-material mixtures were prepared by mixing Li₂CO₃, Nb₂O₅ and MgO with each other so as to make the “Li/Nb” value the following values: 0.8868, 0.9048, 0.9231, 0.9305, 0.9380, 0.9417, 0.9421, 0.9429, 0.9436, 0.9444, 0.9455, 0.9531, 0.9685, and 0.9802; and additionally so as to make an MgO molar ratio 0.05 to a sum of LiNbO₃ and MgO (i.e., the “MgO/(MgO+LiNbO₃)” value). The prepared raw-material mixtures were calcined at 1,000° C. for 10 hours, and were thereafter put in a crucible made of platinum, respectively. Then, the raw-material mixtures were melted by high-frequency induction heating. The melting temperature was 1,300° C. A seed crystal was immersed into each of the resulting raw-material mixture melts, and was then pulled up at a pull-up speed of 5 mm/hr while revolving it at a speed of 10 rpm. Thus, single crystals, which had a diameter of about 80 mm and a length of about 60 mm, were obtained. The used seed crystal was an LN single crystal which had been cut out in the orientation of a targeted axis. The thus obtained magnesium/lithium niobate single crystals were numbered #51 through #64.

After subjecting each of the magnesium/lithium niobate single crystals #51 through #64 to a reduction treatment in the same manner as described for the magnesium/lithium niobate single crystals #31 through #44, wafers for measurement were fabricated likewise. Then, measurements were carried out to the measurement wafers in the same manner as described above in items (III) through (V) to find the Curie temperatures, flawless wafer yields and volumetric resistivities of the respective magnesium/lithium niobate single crystals #51 through #64. Table 4 shows results of the measurements all together.

TABLE 4

| | #51 | #52 | #53 | #54 | #55 | #56 | #57 | #58 | #59 | #60 |
|---|---|---|---|---|---|---|---|---|---|---|
| “Li/Nb” in | 0.8868 | 0.9048 | 0.9231 | 0.9305 | 0.9380 | 0.9417 | 0.9421 | 0.9429 | 0.9436 | 0.9444 |
| Melt | | | | | | | | | | |
| MgO | 5.00 | 5.00 | 5.00 | 5.00 | 5.00 | 5.00 | 5.00 | 5.00 | 5.00 | 5.00 |
| Concentration | | | | | | | | | | |
| (% by mole) | | | | | | | | | | |
| Curie Temp. in | 1209.1 | 1209.5 | 1209.4 | 1209.4 | 1209.6 | 1209.9 | 1210.3 | 1211.1 | 1210.6 | 1210.1 |
| Upper Section | | | | | | | | | | |
| (° C.) | | | | | | | | | | |
| Curie Temp. in | 1208.2 | 1208.9 | 1209.0 | 1209.1 | 1209.4 | 1209.6 | 1210.0 | 1210.8 | 1210.4 | 1210.0 |
| Lower Section | | | | | | | | | | |
| (° C.) | | | | | | | | | | |
| Difference | 0.9 | 0.6 | 0.4 | 0.3 | 0.2 | 0.3 | 0.3 | 0.3 | 0.2 | 0.1 |
| between Upper | | | | | | | | | | |
| Section and | | | | | | | | | | |
| Lower | | | | | | | | | | |
| Section's | | | | | | | | | | |
| Curie Temps. | | | | | | | | | | |
| Flawless | 67.1 | 80.1 | 82.3 | 84.0 | 86.5 | 88.6 | 98.9 | 96.1 | 94.3 | 95.3 |
| Wafer Yield | | | | | | | | | | |
| (%) | | | | | | | | | | |
| Volume | 2.43 × | 3.21 × | 3.31 × | 4.11 × | 3.11 × | 5.15 × | 4.32 × | 2.31 × | 3.01 × | 2.36 × |
| Resistivity | 10⁹ | 10⁹ | 10⁹ | 10⁹ | 10⁹ | 10⁹ | 10⁹ | 10⁹ | 10⁹ | 10⁹ |
| (Ω · cm) | | | | | | | | | | |

| | #61 | #62 | #63 | #64 |
|---|---|---|---|---|
| “Li/Nb” in | 0.9455 | 0.9531 | 0.9685 | 0.9802 |
| Melt | | | | |
| MgO | 5.00 | 5.00 | 5.00 | 5.00 |
| Concentration | | | | |
| (% by mole) | | | | |
| Curie Temp. in | 1211.1 | 1210.4 | 1210.3 | 1209.8 |
| Upper Section | | | | |
| (° C.) | | | | |
| Curie Temp. in | 1210.8 | 1209.8 | 1209.6 | 1209.1 |
| Lower Section | | | | |
| (° C.) | | | | |
| Difference | 0.3 | 0.6 | 0.7 | 0.7 |
| between Upper | | | | |
| Section and | | | | |
| Lower | | | | |
| Section's | | | | |
| Curie Temps. | | | | |
| Flawless | 89.9 | 84.3 | 80.1 | 63.2 |
| Wafer Yield | | | | |
| (%) | | | | |
| Volume | 5.10 × | 4.54 × | 6.01 × | 5.02 × |
| Resistivity | 10⁹ | 10⁹ | 10⁹ | 10⁹ |
| (Ω · cm) | | | | |

It was found out from the results shown in Table 4 that the flawless wafer yield was 80% or more when the magnesium/lithium niobate single crystals #52 through #63 were prepared. That is, it was found out that the flawless wafer yield is high when the atomic ratio between Li and Nb satisfies 0.9048≤(Li/Nb)≤0.9685. It is believed that the resultant flawless wafer yield is affected by the uniformity or homogeneity of single crystal. It is believed conversely that a high flawless wafer yield signifies that the uniformity or homogeneity of single crystal is high. Note that, although Tables 3 and 4 give the results observed about the magnesium/lithium niobate single crystals, it is possible to speculate rationally that similar results are expected from magnesium/lithium tantalate crystals as well, because a magnesium/lithium niobate single crystal and magnesium/lithium tantalate single crystal have crystal structures that are similar to one another.

### Measurement on Thermal Conductivity of Magnesium/Lithium Niobate Single Crystal

The lithium niobate single crystal #20, and the magnesium/lithium niobate single crystals #23 and #25 were used in a quantity of two, respectively, to fabricate wafers for thermal conductivity measurement. A plate having a thickness of about 1 mm was cut from out of a site that was off from the upper end of each of the single crystals by 10 mm. After carrying out a reduction treatment in the same manner as described above, the respective plates were polished to make measurement wafers with 1 mm in thickness. Note that, in the final polishing, a system of mechanochemical polishing by colloidal silica was adopted.

The lithium niobate single crystal #20 exhibited an Li/Nb value of 0.9433, and had an MgO concentration of 0% by mole. The magnesium/lithium niobate single crystal #23 exhibited an Li/Nb value of 0.9433, and had an MgO concentration of 3% by mole. The magnesium/lithium niobate single crystal #25 exhibited an Li/Nb value of 0.9433, and had an MgO concentration of 5% by mole.

The wafers fabricated from the lithium niobate single crystal #20 were labeled substrates according to Comparative Example No. 1. The wafers fabricated from the magnesium/lithium niobate single crystal #23 and #25 were labeled substrates according to Example No. 1 and Example No. 2. Since the single crystals were used in a quantity of two respectively, each of the wafers will be hereinafter referred to as Example No. 1-1, Example No. 1-2, Example No. 2-1, Example No. 2-2, Comparative Example No. 1-1, and Comparative Example No. 1-2.

Note that the wafers, which were used for measuring the thermal conductivities on this occasion, were made into a 128-deg. Y-cut X-propagation substrate, which had a diameter of ϕ 100 mm (or ϕ 4 inches) and a thickness of about 0.35 mm, respectively. Moreover, the used measurement plates were cut to a size of 10-mm length×10-mm width from out of the wafers, respectively.

The wafers were measured by a laser flash method at 25° C. in air to find the thermal conductivities in the Z-axis direction. A method of least square was followed to compute the thermal conductivities. A density, which was employed at the time of computing the thermal conductivities, was 4.6 g/cm³ for all of the sample wafers. Note that the density employed herein was an averaged value of densities which were obtained by actually measuring the respective sample wafers. Thermal conductivities of the sample wafers were measured five times each, and then their averaged values were computed. Table 5 shows results of the computations.

Moreover, “DSM-8103” produced by TOA DKK Co., Ltd. was used to measure volume resistivities of the respective measurement wafers.

TABLE 5

| | Comp. | Comp. | | | | |
|---|---|---|---|---|---|---|
| | Ex. | Ex. | Ex. | Ex. | Ex. | Ex. |
| | No. | No. | No. | No. | No. | No. |
| | 1-1 | 1-2 | 1-1 | 1-2 | 2-1 | 2-2 |
| “Li/Nb” in | 0.9433 | 0.9433 | 0.9433 | 0.9433 | 0.9433 | 0.9433 |
| Melt | | | | | | |
| MgO | 0.00 | 0.00 | 3.00 | 3.00 | 5.00 | 5.00 |
| Concentration | | | | | | |
| (% by mole) | | | | | | |
| Thickness | 0.345 | 0.344 | 0.350 | 0.351 | 0.349 | 0.349 |
| (mm) | | | | | | |
| Thermal | 1.186 | 1.199 | 1.381 | 1.380 | 1.408 | 1.408 |
| Diffusion | | | | | | |
| Factor (mm²/s) | | | | | | |
| Specific Heat | 0.668 | 0.669 | 0.652 | 0.644 | 0.658 | 0.658 |
| (J/g/K) | | | | | | |
| Thermal | 3.646 | 3.691 | 4.145 | 4.089 | 4.258 | 4.260 |
| Conductivity | | | | | | |
| (W/mK) | | | | | | |
| Volume | 2.51 × | 3.12 × | 4.53 × | 4.15 × | 3.31 × | 2.13 × |
| Resistivity | 10⁹ | 10⁹ | 10⁹ | 10⁹ | 10⁹ | 10⁹ |
| (Ω · cm) | | | | | | |

It was found out from the results shown in Table 5 that the substrates according to Example Nos. 1 and 2 exhibited a higher thermal conductivity than the substrate according to Comparative Example No. 1 did. Moreover, it was also found out that the substrate according to Example No. 2, whose MgO concentration was 5% by mole, exhibited a higher thermal conductivity than did the substrate according to Example No. 1 whose MgO concentration was 3% by mole.

Moreover, it is speculated that the MgO concentration, which falls in a range of from 1% by mole to 9% by mole, makes a produced substrate exhibit a higher thermal conductivity than does the MgO concentration which is 0% by mole.

In addition, according to the results on the flawless wafer yield shown in Table 2, the MgO concentration, which was 8% by mole or more, made the resultant magnesium/lithium niobate single crystals exhibit a smaller flawless wafer yield than did the MgO concentration which was 5% by mole. It is believed that the resulting flawless wafer yield is affected by the uniformity or homogeneity of single crystal. It is also believed that the higher the uniformity or homogeneity of single crystal is the higher the thermal conductivity is. Consequently, it seems that the substrate, which is produced from a magnesium/lithium niobate single crystal having an MgO concentration of 8% by mole or more, exhibits a smaller thermal conductivity than does a substrate which is produced from another magnesium/lithium niobate single crystal having an MgO concentration of 5% by mole.

From a viewpoint of the thermal conductivity, it is therefore found out that the MgO concentration preferably falls in a range of from 1% by mole or more to 7% by mole or less, or, more preferably, from 3% by mole or more to 6% by mole or less.

Moreover, it is possible to say that the percent-by-mole MgO concentration indicates the percent-by-mole Mg content proportion in the resulting magnesium/lithium niobate single crystal.

### Measurement on Thermal Conductivity of Magnesium/Lithium Niobate Single Crystal while Changing Measurement Temperature

The substrates according to Example No. 1 and Comparative Example No. 1 were measured to find the thermal conductivities while altering the measurement temperature. Note that the wafers, which were used for measuring the thermal conductivities on this occasion, were undergone the reduction treatment and were then made into a 128-deg. Y-cut X-propagation substrate, which had a diameter of ϕ 100 mm (or ϕ 4 inches) and a thickness of about 1.00 mm, respectively. Moreover, the used measurement plates were cut out to a size of 10-mm length×10-mm width from out of the wafers, respectively.

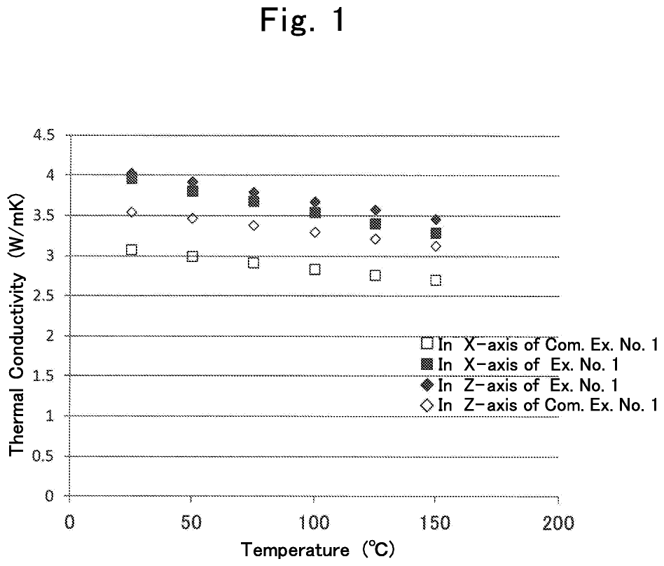

The substrates according to Example No. 1 and Comparative Example No. 1 were measured to find the X-axis-direction thermal conductivities and Z-axis-direction thermal conductivities at 25° C., 50° C., 75° C., 100° C., 125° C. and 150° C. in air. A method of least square was followed to compute the thermal conductivities. A density, which was employed at the time of computing the thermal conductivities, was 4.6 g/cm³ for all of the sample substrates. Note that the density employed herein was an averaged value of densities which were obtained by actually measuring the respective sample substrates. Thermal conductivities of the sample substrates were measured five times each, and then their averaged values were computed. Table 6 shows, and FIG. 1 illustrates results of the computations. Note that, in Table 6, the wafers, which were used for measuring the thermal conductivities, are referred to as Example No. 1-3 and Comparative Example No. 1-3.

TABLE 6

| | |
|---|---|
| X-axis Thermal | Z-axis Thermal |
| Conductivity (W/mK) | Conductivity (° C.) |

| Temperature | Comp. Ex. | Ex. | Comp. Ex. | Ex. |
|---|---|---|---|---|
| (° C. ) | No. 1-3 | No. 1-3 | No. 1-3 | No. 1-3 |
| 25 | 3.079 | 3.969 | 3.548 | 4.033 |
| 50 | 2.998 | 3.811 | 3.472 | 3.926 |
| 75 | 2.919 | 3.684 | 3.385 | 3.798 |
| 100 | 2.840 | 3.547 | 3.302 | 3.679 |
| 125 | 2.766 | 3.408 | 3.220 | 3.579 |
| 150 | 2.708 | 3.293 | 3.131 | 3.465 |

As shown in Table 6 and illustrated in FIG. 1, the substrate according to Example No. 1 resulted in exhibiting a higher thermal conductivity not only in the X-axis direction but also in the Z-axis direction than did the substrate according to Comparative Example No. 1 in a temperature range of from 25° C. to 150° C. That is, it was found out that the substrate according to Example No. 1 was superior to the substrate according to Comparative Example No. 1 in the heat dissipating or radiating property in the temperature range of from 25° C. to 150° C. In particular, it was also found out that the substrate according to Example No. 1 was superb in the heat dissipating or radiating property even at room temperature, because the substrate according to Example No. 1 exhibited an extremely high thermal conductivity not only in the X-axis direction but also in the Z-axis direction even at 25° C. (i.e., at around room temperature) as well.

### Production for Magnesium/Lithium Tantalate Single Crystal

A raw-material mixture was prepared by mixing Li₂CO₃, Ta₂O₅ and MgO with each other by a ball mill so as to make an “Li/Ta” value 0.9433; and additionally so as to make an MgO molar ratio 0.05 to a sum of LiTaO₃ and MgO (i.e., the “MgO/(MgO+LiTaO₃)” value). The prepared raw-material mixture was calcined at 1,200° C. for 10 hours, and was thereafter put in a crucible made of iridium. Then, the raw-material mixture was melted by high-frequency induction heating. The melting temperature was 1,710° C. A seed crystal, which had been cut out in a predetermined orientation, was immersed into the resulting raw-material mixture melt, and was then pulled up at a pull-up speed of 5 mm/hr while revolving it at a speed of 10 rpm. Thus, a single crystal, which had a diameter of about 100 mm and a length of about 60 mm, was obtained. The used seed crystal was an LT single crystal which had been cut out in a predetermined orientation.

Plates, each of which had a thickness of 1 mm, were cut out from the obtained single crystal at a position away from the upper end by 10 mm. The cut-out plates were subjected to a reduction treatment which was carried out in the same manner as the reduction treatment as described above for the measurement wafers formed of the magnesium/lithium niobate single crystals. One of the opposite faces of the plates was mirror polished to fabricate wafers for measurement. Note that, in the final polishing, a system of mechanochemical polishing by colloidal silica was adopted.

The wafers, which had been prepared from the magnesium/lithium tantalate single crystal, had a white color before the reduction treatment, and had a blue-gray color after the reduction treatment. Moreover, since the white color or blue-gray color of the wafers was uniform or homogeneous in the respective wafers as a whole, it was understood at a glance that magnesium, the additive element, was added uniformly or homogenously.

### Production for LT Single Crystal

A raw-material mixture was prepared by mixing Li₂CO₃ and Ta₂O₅ with each other by a ball mill so as to make an “Li/Ta” value 0.9433. The prepared raw-material mixture was calcined at 1,200° C. for 10 hours, and was thereafter put in a crucible made of iridium. Then, the raw-material mixture was melted by high-frequency induction heating. The melting temperature was 1,710° C. A seed crystal, which had been cut out in a predetermined orientation, was immersed into the resulting raw-material mixture melt, and was then pulled up at a pull-up speed of 5 mm/hr while revolving it at a speed of 10 rpm. Thus, a single crystal, which had a diameter of about 100 mm and a length of about 60 mm, was obtained. The used seed crystal was an LT single crystal which had been cut out in a predetermined orientation.

Plates, each of which had a thickness of 1 mm, were cut out from the obtained single crystal at a position away from the upper end by 10 mm. The cut-out plates were subjected to a reduction treatment. One of the opposite faces of the plates, which had undergone the reduction treatment, was mirror polished to fabricate wafers for measurement. Note that, in the final polishing, a system of mechanochemical polishing by colloidal silica was adopted. Moreover, the reduction treatment was carried out to the lithium tantalate single crystal in the same manner as the reduction treatment which the magnesium/lithium tantalate single crystal had undergone.

### Measurement on Thermal Conductivity of Magnesium/Lithium Tantalate Single Crystal

The substrates formed of the reduced magnesium/lithium tantalate single crystal were labeled substrates according to Example No. 2. The substrates formed of the reduced lithium tantalate single crystal were labeled substrates according to Comparative Example No. 2.

The substrates according to Example No. 2 and Comparative Example No. 2 were measured at 25° C. to find the X-axis-direction and Z-axis-direction thermal diffusion factors, and the X-axis-direction and Z-axis-direction thermal conductivities in the same manner as the above-described laser flash method. Table 7 shows results of the measurements. A density, which was employed at the time of computing the thermal conductivities, was 7.45 g/cm³ for all of the sample substrates. Note that the density employed herein was an averaged value of densities which were obtained by actually measuring the respective sample substrates. Moreover, the substrates according to Comparative Example No. 2 exhibited a volume resistivity of 4.53×10¹¹ Ω·cm, and the substrates according to Example No. 2 exhibited a volume resistivity of 5.11×10¹¹ Ω·cm.

TABLE 7

| | Comp. Ex. No. 2 | Ex. No. 2 |
|---|---|---|
| Li/Ta in Melt | 0.9433 | 0.9433 |
| MgO Concentration | 0.00 | 5.00 |
| (% by mole) | | |
| X-axis Thermal | 1.100 | 1.283 |
| Diffusion Factor | | |
| (mm^{2/}s) | | |
| X-axis Thermal | 3.271 | 3.758 |
| Conductivity | | |
| (W/mK) | | |
| Z-axis Therma1 | 1.379 | 1.487 |
| Diffusion Factor | | |
| (mm²/s) | | |
| Z-axis Thermal | 4.101 | 4.357 |
| Conductivity | | |
| (W/mK) | | |

As Table 7 shows, the substrates according to Example No. 2 exhibited higher thermal conductivities in the X-axis direction as well as in the Z-axis direction at 25° C. than the substrates according Comparative Example No. 2 did. Moreover, the substrates according to Example No. 2 exhibited higher thermal diffusion factors in the X-axis direction as well as in the Z-axis direction at 25° C. than the substrates according Comparative Example No. 2 did.

Moreover, the following will not be described herein in detail. The lithium tantalate single crystal was found out to exhibit a Curie temperature of 603° C. On the other hand, the magnesium/lithium tantalate single crystal was found out to exhibit a Curie temperature of from 620° C. or more to 720° C. or less.

From the results described above, it was found out that a substrate for surface acoustic wave element exhibits a high thermal conductivity, and enables manufacturers to form thin plates or sheets, when the substrate comprises: a magnesium/lithium niobate single crystal in which an atomic ratio between Li and Nb satisfies 0.9048≤(Li/Nb)≤0.9685, and whose Mg content proportion is from 1% by mole or more to 9% by mole or less; or a magnesium/lithium tantalate single crystal in which an atomic ratio between Li and Ta satisfies 0.9048≤(Li/Ta)≤0.9685, and whose Mg content proportion is from 1% by mole or more to 9% by mole or less. It is therefore speculated that a device, within which surface acoustic wave elements are laminated highly densely, is made likely to radiate or dissipate heats by using the surface-acoustic-wave-element substrate exhibiting a high thermal conductivity.

1: A substrate, comprising:
a magnesium/lithium niobate single crystal in which an atomic ratio between Li and Nb satisfies 0.9048≤(Li/Nb)≤0.9685, and wherein a Mg content proportion is from 1% by mole or more to 9% by mole or less; or
a magnesium/lithium tantalate single crystal in which an atomic ratio between Li and Ta satisfies 0.9048≤(Li/Ta)≤0.9685, and wherein a Mg content proportion is from 1% by mole or more to 9% by mole or less.

2: The substrate of claim 1, wherein:
the magnesium/lithium niobate single crystal exhibits the atomic ratio between Li and Nb satisfying 0.9421≤(Li/Nb)≤0.9443; or
the magnesium/lithium tantalate single crystal exhibits the atomic ratio between Li and Ta satisfying 0.9421≤(Li/Ta)≤0.9443.

3: The substrate of claim 1, wherein the Mg content proportion in the magnesium/lithium niobate single crystal or the magnesium/lithium tantalate single crystal is from 1% by mole or more to 6% by mole or less.

4: The substrate of claim 1, wherein the substrate has a thickness of 1 mm or less.

5: The substrate of claim 1, wherein the substrate exhibits a volume resistivity of 9.9×10¹² Ω·cm or less.

6: The substrate of claim 1, wherein:
the magnesium/lithium niobate single crystal exhibits a Curie temperature of from 1,150° C. or more to 1,215° C. or less; or
the magnesium/lithium tantalate single crystal exhibits a Curie temperature of from 620° C. or more to 720° C. or less.

7: A production process for a substrate, the production process comprising:
preparing a raw-material mixture by mixing lithium carbonate (Li₂CO₃) making a lithium source, niobium pentoxide (Nb₂O₅) making a niobium source, and magnesium oxide (MgO) making a magnesium source with each other so as to satisfy following requirements (1) and (2);
(1) an atomic ratio between Li and Nb: 0.9048≤(Li/Nb)≤0.9685; and
(2) an MgO molar ratio with respect to a sum of LiNbO₃ and MgO assuming that LiNbO₃ is generated from Li₂CO₃ and Nb₂O₅: 0.01≤{MgO/(MgO+LiNbO₃)}≤0.09;
a melting the raw-material mixture;
performing a single-crystal growth by growing a magnesium/lithium niobate single crystal by immersing a seed crystal into the raw-material mixture melt and then pulling it up therefrom; and
fabricating a substrate from the magnesium/lithium niobate single crystal obtained at the single-crystal growth.

8: The production process of claim 7, wherein the requirement (1) is adapted as follows in the raw-material mixture melting:
(1) an atomic ratio between Li and Nb: 0.9421≤(Li/Nb)≤0.9443.

9: A production process for a substrate, the production process comprising:
preparing a raw-material mixture by mixing lithium carbonate (Li₂CO₃) making a lithium source, tantalum pentoxide (Ta₂O₅) making a tantalum source, and magnesium oxide (MgO) making a magnesium source with each other so as to satisfy following requirements (3) and (4);
(3) an atomic ratio between Li and Ta: 0.9048≤(Li/Ta)≤0.9685; and
(4) an MgO molar ratio with respect to a sum of LiTaO₃ and MgO assuming that LiTaO₃ is generated from Li₂CO₃ and Ta₂O₅: 0.01≤{MgO/(MgO+LiTaO₃)}≤0.09;
melting the raw-material mixture;
performing a single-crystal growth by growing a magnesium/lithium tantalate single crystal by immersing a seed crystal into the raw-material mixture melt and then pulling it up therefrom; and
fabricating a substrate from the magnesium/lithium tantalate single crystal obtained at the single-crystal growth.

10: The production process of claim 9, wherein the requirement (3) is adapted as follows in the raw-material mixture melting:
(3) an atomic ratio between Li and Ta: 0.9421≤(Li/Ta)≤0.9443.

11: The production process of claim 7, wherein the substrate is made to have a thickness of 1 mm or less in the substrate fabrication.

12: The production process of claim 7, wherein:
the substrate fabrication comprises a reduction treatment for the substrate; and
the reduction treatment comprises reducing the substrate by accommodating the substrate and a reducing agent, which comprises an alkali metal compound, in a treatment container, and then retaining the treatment container at a temperature of 200° C. or more and less than a Curie temperature of a single crystal, which constitutes the substrate, under reduced pressure.

13: The production process of claim 9, wherein the substrate is made to have a thickness of 1 mm or less in the substrate fabrication.

14: The production process of claim 9, wherein:
the substrate fabrication comprises a reduction treatment for the substrate; and
the reduction treatment comprises reducing the substrate by accommodating the substrate and a reducing agent, which comprises an alkali metal compound, in a treatment container, and then retaining the treatment container at a temperature of 200° C. or more and less than a Curie temperature of a single crystal, which constitutes the substrate, under reduced pressure.
